(19) United States
(12) Patent Application Publication
(10) Pub. No.: US 2021/0103688 A1
(43) Pub. Date: Apr. 8, 2021

(54) Driveline Model

(71) Applicant: Romax Technology Limited, Nottingham (GB)

(72) Inventors: Barry James, Cranage (GB); Kathryn Taylor, Nottingham (GB)

(73) Assignee: ROMAX TECHNOLOGY LIMITED, Nottingham (GB)

(21) Appl. No.: 16/074,093

(22) PCT Filed: Feb. 1, 2017
(86) PCT No.: PCT/IB2017/050541

§ 371 Date: Jul. 31, 2018

(30) Foreign Application Priority Data
Feb. 2, 2016 (GB) 1601849.1
Apr. 19, 2016 (GB) 1606813.2

(51) Int. Cl. G06F 30/15; F16H 57/00; G06F 30/17

(52) U.S. Cl. CPC G06F 30/15; F16H 2057/0087; G06F 30/17; F16H 57/00

(57) ABSTRACT

A system for modelling a driveline, wherein the driveline comprises a plurality of components. The system comprises: a component-efficiency-processor (104a, 104b) configured to: receive a component model (102a, 102b) for one or more of the plurality of components; and generate a component-efficiency-map for the one or more components based on the received corresponding component model (102a, 102b). The system also comprises a driveline-efficiency-processor (106) configured to generate a driveline-efficiency-metric (108) for the driveline based on (i) the component-efficiency-maps for the one or more of the plurality of components, (ii) a driveline-layout (110) representative of a layout/inter-engagement of the plurality of components, and (iii) one or more driving-profiles.

### TECHNICAL FIELD

The present invention relates to systems for modelling drivelines, and in particular for generating driveline efficiency metrics.

### BACKGROUND ART

US2015/0347670 A1 (JAMES) discloses an approach for calculating driveline efficiency. However an appropriate component efficiency map is not generated as and when required, it is not immediately available for the driveline efficiency processor. This also means that the user may have to spend time importing a map from another source or modelling the efficiency in another software package. The efficiency map would have to be calculated elsewhere and imported. An efficiency map generally has limits in terms of torque and speed for a given gearbox and motor design, and if the operating speed range is changed the motor/gearbox has to be redesigned, which changes the efficiency map. Since the component efficiency maps are not all generated by the same processors, they may not be compatible with each other.

The present invention provides this functionality in a single modelling system.

### BRIEF DESCRIPTION OF THE INVENTION

According to a first aspect of the invention, there is provided a system for modelling a driveline, wherein the driveline comprises a plurality of components, the system comprising:
a component-efficiency-processor configured to:
   receive a component model for one or more of the plurality of components; and
   generate a component-efficiency-map for the one or more components based on the received corresponding component model; and
a driveline-efficiency-processor configured to generate a driveline-efficiency-metric for the driveline based on (i) the component-efficiency-maps for the one or more of the plurality of components, (ii) a driveline-layout representative of a layout/inter-engagement of the plurality of components, and (iii) one or more driving-profiles.

The driveline-efficiency-processor may be configured to generate one or more additional driveline-metrics based on the received corresponding component model. The one or more additional driveline-metrics may be representative of one or more of the following characteristics: packaging size, power rating, durability, driveability, noise and vibration characteristics.

The component-efficiency-processor may be configured to generate the component-efficiency-map based on a component-detail-level.

The component-efficiency-processor may be configured to:
make different physical or mathematical assumptions when generating the component-efficiency-map based on the component-detail-level; and/or
change the number of points used for generating the component-efficiency-map based on the component-detail-level.

The component models may comprise component-form-information representative of physical dimensions of the associated component. The driveline-efficiency-processor may be further configured to:
generate a driveline-packaging-metric based on (i) the component-form-information for the one or more of the plurality of components, and (ii) the driveline-layout.

The driveline-efficiency-processor may be further configured to:
convert one or more driving-profiles from the time-domain into a non-time-varying form; and
generate the driveline-efficiency-metric based on the non-time-varying form of the one or more driving-profiles.

The driveline-efficiency-processor may be further configured to generate the driveline-efficiency-metric for the driveline based on a time-varying mass of a vehicle associated with the driveline over the one or more driving-profiles.

The driving-profile may comprise information about the time-varying mass of the vehicle.

The driveline-efficiency-processor may be further configured to generate the driveline-efficiency-metric for the driveline based on a variable gradient associated with the one or more driving-profiles.

The driving-profile may comprise information about the variable gradient.

The driveline-efficiency-processor may be configured to apply a tractive force equation when generating the driveline-efficiency-metric. The tractive force equation may be configured to determine tractive force required for a time-varying mass and/or a variable gradient associated with the one or more driving-profiles.

The driveline-efficiency-processor may be further configured to:
process a plurality of different drivelines and generate one or more driveline-metrics for each of the plurality of drivelines;
use the driveline-metrics to select a driveline, considering one or more of a range of performance targets.

The plurality of drivelines may have variations in one or more or the following inputs:
driveline-layouts;
component models;
component-efficiency-maps;
component parameters;

wherein each combination of inputs represents a different driveline.

The driveline-efficiency-processor may be further configured to:
process a driveline with a plurality of different control parameters and generate one or more driveline-metrics for each of the plurality of control parameters;
use the driveline-metrics to select a set of control parameters, considering one or more of a range of performance targets.

According to a further aspect of the invention, there is provided a driveline-efficiency-processor for a driveline comprising a plurality of components, wherein the driveline can be operated according to a plurality of control-states-of-operation, wherein the driveline-efficiency-processor comprises:

an analysis-block configured to:
receive a plurality of component-efficiency-maps that are associated with respective ones of the plurality of components in the driveline;
receive a driveline-layout representative of a layout/inter-engagement of the plurality of components;
provide as an output, a set of operational-matrices for each component, wherein the set includes a matrix for each control-state-of-operation; and

a control-strategy-application-block configured to:
receive the set of operational-matrices;
receive a driving-profile that represents a plurality of vehicle-operational-requirements;
process the driving-profile and the set of operational-matrices for each component to determine one or more control-state-maps;
for the one or more control-state-maps, process the driving-profile and the set of operational-matrices for each component to determine a driveline-efficiency-metric; and provide as an output, data representative of (i) a control-state-map associated with the driveline-efficiency-metric; and/or (ii) the driveline-efficiency-metric.

The matrix for each control-state-of-operation in the set of operational-matrices may comprise information about the efficiency of an associated component for a plurality of vehicle operational requirements (such as speed and acceleration values).

The control-strategy-application-block may be configured to:
a) determine a latest-control-state-map;
b) determine latest-component-efficiency-values for the driveline over the driving profile based on the set of operational-matrices and the latest-control-state-map; and
c) determine whether or not the latest-component-efficiency-values satisfy a predetermined criteria; and
   if the latest-component-efficiency-values satisfy the predetermined criteria, then:
      determine the driveline-efficiency-metric based on the latest-component-efficiency-values and the latest-control-state-map; and
      provide as an output, data representative of (i) the latest-control-state-map;
      and/or (ii) the driveline-efficiency-metric;
   if the latest-component-efficiency-values do not satisfy the predetermined criteria, then:
      determine a revised latest-control-state-map based on the latest-component-efficiency-values and return to step b).

Each control-state-map may define one or more switchover-thresholds between different control-states-of-operation. The control-strategy-application-block may be configured to determine a revised latest-control-state-map by modifying the switchover-threshold(s).

The control-strategy-application-block may be configured to determine the latest control-state-map by:
determining a net-battery-charge-increase value over the driving-profile for a plurality of control-state-maps;
comparing the net-battery-charge-increase values with each other or a predetermined threshold; and
based on the comparison, selecting one of the plurality of control-state-maps as the latest control-state-map.

The control-strategy-application-block may be configured to determine the latest-control-state-map at step a) using initial-component-efficiency-values.

The control-strategy-application-block may be configured to calculate the driveline-efficiency-metric and control-state-map using an iterative process:
process the set of operational-matrices for each component and initial component-efficiency-values to determine an initial driveline-efficiency-metric for each control-state-of-operation;
process the initial driveline-efficiency-metric for each control-state-of-operation in order to determine an initial control-state-map;
optionally, alter a power-threshold-line between different control-states-of-operation to achieve a specified target value of net-battery-charge-increase over the driving profile;
calculate updated component efficiency values over the driving-profile using the control-state-map;
compare the component efficiency values over the driving-profile with those calculated in a previous iteration (or, in the first iteration, with the initial component-efficiency-values);
if the component efficiency values over the driving-profile have not converged to within a defined limit, repeat the process from the beginning using the updated component efficiency values;
if the component efficiency values over the driving-profile have converged to within a defined limit, provide as an output data representative of (i) a final control-state-map and/or (ii) the final driveline-efficiency-metric.

The control-states-of-operation may comprise one or more of:
(i) one of a plurality of modes of propulsion;
(ii) one of a plurality of gear ratios; and
(iii) one of a plurality of power-split-modes-of-operation.

According to a further aspect of the invention, there is provided a method of modelling a driveline, wherein the driveline comprises a plurality of components, the method comprising:
receiving a component model for one or more of the plurality of components; and
generating a component-efficiency-map for the one or more components based on the received corresponding component model; and
generating a driveline-efficiency-metric for the driveline based on (i) the component-efficiency-maps for the one or more of the plurality of components, (ii) a driveline-layout representative of a layout/inter-engagement of the plurality of components, and (iii) one or more driving-profiles.

According to a further aspect of the invention, there is provided a method of processing for a driveline, wherein the driveline comprises a plurality of components, and wherein the driveline can be operated according to a plurality of control-states-of-operation, wherein the method comprises:
receiving a plurality of component-efficiency-maps that are associated with respective ones of the plurality of components in the driveline;
receiving a driveline-layout representative of a layout/inter-engagement of the plurality of components;
determining a set of operational-matrices for each component, wherein the set includes a matrix for each control-state-of-operation; and
receiving a driving-profile that represents a plurality of vehicle-operational-requirements;
processing the driving-profile and the set of operational-matrices for each component to determine one or more control-state-maps;
for the one or more control-state-maps, processing the driving-profile and the set of operational-matrices for each component to determine a driveline-efficiency-metric; and
providing as an output, data representative of (i) a control-state-map associated with the driveline-efficiency-metric; and/or (ii) the driveline-efficiency-metric.

There may be provided a computer program, which when run on a computer, causes the computer to configure any apparatus, including a processor, controller or device disclosed herein or perform any method disclosed herein. The computer program may be a software implementation, and the computer may be considered as any appropriate hardware, including a digital signal processor, a microcontroller, and an implementation in read only memory (ROM), erasable programmable read only memory (EPROM) or electronically erasable programmable read only memory (EEPROM), as non-limiting examples.

The computer program may be provided on a computer readable medium, which may be a physical computer readable medium such as a disc or a memory device, or may be embodied as a transient signal. Such a transient signal may be a network download, including an internet download.

### BRIEF DESCRIPTION OF DRAWINGS

Embodiments of the present invention will now be described by way of example and with reference to the accompanying drawings in which:

FIG. 1 shows schematically a computer-implemented system for modelling a driveline and generating a driveline-metric;

FIG. 2a shows an example of a driveline of a hybrid vehicle;

FIG. 2b shows an example propulsion-mode-map;

FIG. 2c shows an example gear-shift-map;

FIG. 2d shows an example simplified gear-shift-map;

FIG. 3 illustrates a forward-facing simulation of a driveline;

FIG. 4 illustrates a backward-facing simulation of a driveline;

FIG. 5 illustrates an example process flow for simulation of a driveline over a driving-profile;

FIG. 6 illustrates an example process flow of the improved method of generating a control-state-map based on a simulation of a driving-profile;

FIG. 7 shows an example of a driveline-efficiency-processor, which can be used to calculate driveline-metrics;

FIG. 8 illustrates schematically a method of operation of the control-strategy-application-block of FIG. 7; and

FIG. 9 illustrates a method of calculating system efficiency.

### DETAILED DESCRIPTION OF THE INVENTION

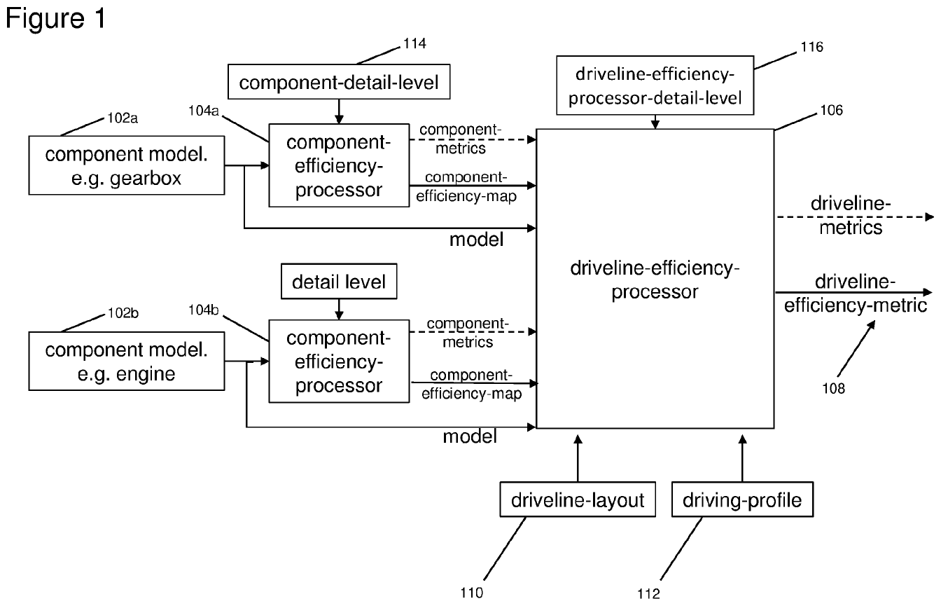

FIG. 1 shows schematically a computer-implemented system for modelling a driveline and generating a driveline-efficiency-metric 108. A driveline-efficiency-metric is an example of a driveline-metric and can be representative of energy consumption over a driving profile. A driveline-metric is a metric relating to the performance of a driveline, for example efficiency, packaging size, power rating, durability, driveability, noise and vibration characteristics. For example, a driveline can be judged on whether one or more of its driveline-metrics satisfy one or more driveline-criteria or other performance targets. For example, for packaging reasons the outer dimensions of key drivetrain components may be represented by a driveline-packaging-metric. In order to ascertain whether the components fit within an available space, the driveline-packaging-metric may be compared with driveline-packaging criteria. In addition to generating a driveline-efficiency-metric, the driveline-efficiency-processor can optionally generate one or more driveline-metrics, including a driveline-packaging-metric.

The driveline includes a plurality of components, non-limiting examples of which include, for example, internal combustion engines, fuel cells, gas turbines, gearboxes, electric machines, shafts, housings, bearings, clutches, terrestrial/aerospace/marine vehicle chassis, wheels, flywheels, batteries, capacitors, and power electronics. The components can be sub-assemblies of components, or individual components.

FIG. 1 shows two example component models 102a, 102b, each of which corresponds to a component that is, or could be, in a driveline. The system can have any number of components. The component models 102a, 102b can include component-functional-information/parameters that define the component. Such parameters can be specific to certain types of components, and include:
For a gearbox: number of speed ratios, value of the speed ratios, position and dimensions of shafts, gears, and bearings.
For an internal combustion engine: number of cylinders, cylinder dimensions, compression ratio, speed and torque ratings, maximum power rating.
For a wheel: diameter, drag coefficient.

The system of FIG. 1 includes a plurality of component-efficiency-processors 104a, 104b, one for each of the component models 102a, 102b. The component-efficiency-processors 104a, 104b can process an associated component model 102a, 102b in order to generate a component-efficiency-map. The processing involved will depend upon the specific type of component in question. Some example efficiency maps for different components are described below.

An efficiency map for a gearbox can be generated by calculating the gearbox power losses over a range of speeds and torques. The main sources of power loss in a gearbox can include gear mesh losses due to sliding friction between the gear teeth, gear churning losses due to splashing of the lubricant, and bearing losses. These power losses can be calculated using, for example, the methods defined in ISO standard 14179.

An efficiency map for an electric machine can be generated by calculating the electric machine power losses over a range of speeds and torques. The main sources of power loss can include copper losses due to electrical resistance in the machine windings, iron losses due to hysteresis and eddy currents, and mechanical losses due to bearing friction and windage.

An efficiency map may be a flat map, in that the efficiency values may be substantially constant for a range of operating conditions.

A component-efficiency-processor 104a, 104b can be configured to generate one or more component-metrics in addition to the component-efficiency-map, by optimising the component for one or more other design targets in addition to efficiency, including but not limited to packaging space, vibration characteristics, and durability. For example, a gearbox component-efficiency-processor could optimise the gearbox layout (number, position, and dimensions of shafts, bearings, gears), macro-geometry, and micro-geometry. In this way, one or more component-metrics can be generated by the component-efficiency-processor 104a, 104b.

The system of FIG. 1 also includes a driveline-efficiency-processor 106 for generating a driveline-efficiency-metric 108, and optionally one or more driveline-metrics. The driveline-efficiency-processor 106 can process at least (i) the component-efficiency-maps for the one or more of the plurality of components, (ii) a driveline-layout 110 and (iii) a driving-profile 112 in order to generate a driveline-efficiency-metric. As will be discussed in more detail below, the driveline-layout 112 is representative of an arrangement/inter-engagement of components in the driveline. The driveline-efficiency-processor 106 may also provide a control-state-map as an output, which can be used to control the driveline in order to achieve the driveline-efficiency-metric, as discussed below. A driveline-efficiency-processor 106 can be configured to optimise the driveline for one or more other driveline-metrics in addition to a driveline-efficiency-metric.

There are several advantages of the system of FIG. 1 that includes both a component-efficiency-processor 104a, 104b for generating a component-efficiency-map, and a driveline-efficiency-processor 106 for generating a driveline-efficiency-metric. These advantages can include, but are not limited to, the following:
Improved processing time for generating the driveline-efficiency-metric 108 for any given component model because an appropriate component-efficiency-map can be generated as and when required by the component-efficiency-processor 104a, 104b, and is immediately available for the driveline-efficiency-processor. For each component model 102a, 102b, the driveline-efficiency-processor can either use an existing component-efficiency-map or can instruct a component-efficiency-processor 104 to generate a component-efficiency-map.
Generating component-efficiency-maps as the simulation runs is convenient because the map is generated automatically when needed and the user does not have to spend time importing a map from another source or modelling the efficiency in another software package. This option is useful for parameter sweeps where the simulation is run multiple times with different component models or component parameters. Some component-efficiency-maps can be generated during the simulation, and some components can take pre-existing maps as inputs rather than generating new component-efficiency-maps. This flexibility is particularly useful when optimising one drivetrain component but keeping the others the same, and has the advantage of speed as no time is spent in generating the new component-efficiency-maps when existing ones are sufficient.
Increased accuracy of the driveline-efficiency-metric 108. This can be because the plurality of component-efficiency-maps can be compatible with each other for example because they are all generated by component-efficiency-processors 104a, 104b in the same system, and because component-efficiency-maps are always up-to-date because they are generated as and when required.

The potential design space for hybrid vehicles is very large, with a wide range of possible driveline-layouts across the entire spectrum of electrification from pure conventional to pure electric powered vehicles, with many options in between. There are many degrees of freedom in the design and control of the drivelines and components. A rapid whole-system simulation, such as the system of FIG. 1, is able to address the multiplicity of options at the concept design stage. The system can complement existing simulation tools by using an appropriate level of modelling detail in order to narrow down the large number of candidate designs to select promising drivelines for detailed design based on one or more driveline-metrics for each candidate design. Computational speed is more important than modelling detail at the concept design stage, yet the model fidelity is sufficient to enable engineering judgements on how to select a driveline from a large number of candidate drivelines.

Traditional vehicle simulations can be computationally intensive, often preventing a full exploration of all of the candidate drivelines in the design space.

The system of FIG. 1, and also other systems disclosed herein, can be used to process many different candidate drivelines, with variations in one or more or the following:
driveline-layouts;
component models;
component-efficiency-maps;
component parameters;

and the resulting driveline-metrics for each candidate driveline can be used to select a driveline from the set of candidates, considering one or more of a range of performance targets.

In addition, the same driveline can be processed with a plurality of different control parameters, which also increases the number of simulations which must be run in order to investigate all options.

Rapid simulation is therefore advantageous in that it enables wider exploration of the design space, considering all of the options for driveline and component design and control.

The driveline-layout 110 can define how the components in the driveline engage/interact with each other. In some examples, the driveline-layout 110 received by the driveline-efficiency-processor 106 can provide information that is used in combination with information stored within the driveline-efficiency-processor 106 to determine how the components in the driveline engage/interact with each other. For example, the driveline-layout 110 may provide an identifier for each component in the driveline, which the driveline-efficiency-processor 106 can use to retrieve an associated component-efficiency-map from a plurality of maps received from component-efficiency-processors 104a, b. The order in which the plurality of components is connected in the driveline can be defined in the driveline layout.

In some examples, the component models 102a, 102b include component-form-information, which can be representative of physical dimensions of the associated component and/or a material from which the component is made. That is, the component models 102a, 102b may include more than just functional definitions of the component.

As shown in FIG. 1, the component models 102a, 102b may be accessible by the driveline-efficiency-processor 106. The driveline-efficiency-processor 106 can therefore generate a driveline-packaging-metric (which is another example of a driveline-metric) based on (i) the component-form-information for the one or more of the plurality of components, and (ii) the driveline-layout.

Advantageously, the system of FIG. 1 can therefore provide information about the efficiency of the driveline (by determining a driveline-efficiency-metric) and also provide information about the form of the driveline (by determining a driveline-size-metric), such as the size and mass of the driveline. Therefore, the design of a driveline can be greatly improved because any drivelines that have an unacceptably high size or mass can be easily identified early in the design process such that further unnecessary calculations of their efficiency can be avoided. It will be appreciated that calculations of efficiency of drivelines can be very complicated and can require a large amount of processing overhead. Therefore, an ability to identify a driveline that has an unsatisfactory form (for example because it is too big or too heavy or because it is the wrong shape to fit into the packaging space available in the vehicle) can greatly reduce the required processing power, and also time, that is required to design a driveline. This advantage can also apply to other driveline-metrics.

In some examples, the component-efficiency-processors 104a, 104b can generate the component-efficiency-map based on a component-detail-level 114. Use of such a component-detail-level 114 can be used to set an appropriate balance between (i) speed of processing, and (ii) precision of the component-efficiency-map that is generated by the component-efficiency-processors 104a, 104b. The component-efficiency-processors 104a, 104b can make different physical or mathematical assumptions about the component efficiency model when generating the component-efficiency-map based on the component-detail-level 114, or change the number of points used for generating the component-efficiency-map based on the component-detail-level 114, for example the number of points in the component-efficiency-map (number of speed points multiplied by number of torque points) at which the efficiency is calculated.

The driveline-efficiency-processor 106 can also receive a driveline-efficiency-processor-detail-level 116. Similarly to the component-detail-level 114 for the component-efficiency-processors, the driveline-efficiency-processor-detail-level 116 can be used to set an appropriate balance between (i) speed of processing, and (ii) precision of the driveline-efficiency-metric that is generated by the driveline-efficiency-processor 106. The driveline-efficiency-processor-detail-level 116 can define the number of vehicle operating points (e.g. speed and acceleration) to be considered, and/or the number of power-split-modes-of-operation to be considered in the control strategy, as will be discussed later.

In the example of FIG. 1, the driveline-efficiency-processor 106 also receives a driving-profile 112. Various driving-profiles are known in the art, including NEDC, WLTP, and Artemis. Typically, these driving-profiles define a speed-time profile.

In some examples, advantageously, the driveline-efficiency-processor 106 can convert a speed-time driving-profile 112 into a speed-acceleration profile. It will be appreciated that such processing changes the representation of the driving-profile 112 from the time domain into the statistical domain. The representation in the statistical domain is an example of a representation of the driving cycle in a non-time-varying form.

It is important to consider real-world driving conditions early in the design process. If a vehicle is designed and optimised for one driving-profile, the vehicle will perform less well under different driving conditions. Time domain modelling can be slow; each timestep is analysed in turn, so the simulation time is proportional to driving-profile duration. Adding more driving-profiles to a time-domain simulation proportionally increases the required computation time. A limited consideration of driving-profiles can lead to solutions that are not robust to variations in driving style.

In examples where the driving-profile is converted into the statistical domain, the driveline-efficiency-processor can perform a single calculation over the speed-acceleration operation space, rather than a separate calculation for each timestep. Thus there is no time penalty for processing a greater number of driving-profiles, and the method can be made more representative of real-world driving by including a wider range of driving-profiles.

In some cases, the driving-profile can include a gradient, which may be a variable/time-varying gradient, which can be incorporated into the simulation to include the effects of a vehicle going up- or downhill. This can be achieved by adding a term to the tractive force equation to represent the component of the gravitational force in the direction of the slope

In road vehicles, the tractive force is the force required at the wheels in order to accelerate the vehicle to meet the driving-profile and to overcome drag forces (which can include air resistance, wheel friction, and road gradient),

F_{tractive}=F_{acceleration}+F_{drag}+F_{gradient}

One formulation of the tractive force equation is:

F_{tractive}=m a(t)+k1 v(t)²+k₂ m g cos θ(t)+m g sin θ(t)

where m is the vehicle mass, a(t) is acceleration, k₁ and k₂ are constants, v(t) is speed, g is the gravitational constant, θ(t) is the road gradient (angle from the horizontal), and (t) indicates that the variable is a function of time.

For small values of θ, the approximation cos θ≈1 can be made. The first term in the equation is the force required to meet the acceleration requirements of the driving-profile, the second term represents air resistance, the third term represents rolling resistance, and the fourth term represents driving up- or downhill. A positive value of θ represents driving uphill, a negative value of θ represents driving downhill, and θ=0 represents driving on a horizontal road.

When the simulation is in the statistical domain, the time-varying gravitational force component (m g sin θ(t)) can be included in the acceleration value of the driving-profile operating points by taking the acceleration values a′ as a′=a(t)+g sin θ(t).

The definition of the driving-profile can include time-varying mass (i.e. a driving-profile that defines mass as a function of time, as well as speed as a function of time). In the statistical domain, time-varying mass can be achieved via a similar method to including road gradients in drive cycles. The tractive force equation can be refactored so that time-varying mass is included in the definition of the non-time-varying acceleration matrix, so the method can be implemented with only minor changes to the definition of driving-profile.

The accelerative force Facceleration required to fulfil the acceleration requirements of the driving-profile is:

F_{acceleration}=m(t) a(t).

This equation can be refactored to separate out the time dependency:

F_{acceleration}=m₀ a m(t)/m₀

where m₀ is a constant mass, and m(t)/m₀ is a factor that represents the deviation from the constant mass through the driving-profile.

The acceleration values a′ of the operating points are given by a′=a(t) m(t)/m₀. If the simulation represents a vehicle that has time-varying mass and the driving-profile has a road gradient, the acceleration values a′ of the operating points are given by a′=a(t) m(t)/m₀+g sin θ(t). This method removes the time-dependency from the tractive force equation, and places it into the definition of the driving-profile. The time-variance of the road gradient and/or vehicle mass is therefore accounted for in the driving-profile definition, enabling the tractive force equation to be applied to the driving-profile operating points in the statistical domain.

Applications of vehicle simulation involving time-varying mass can include, but are not limited to, the following:
1) Passenger-carrying vehicles that vary in usage—for example, the number of passengers along a route. The method could be useful for bus/train applications, especially if the passenger weight is a significant proportion of the vehicle weight. For hybrid vehicles in particular, even a small mass change can have a significant effect on fuel consumption.
2) On-highway HDVs, particularly delivery vehicles where the payload varies with time. The method could be useful for fleet operators—the driving-profile including time-varying mass is even more specific to the fleet operator, so it is an advantage to optimise the driveline for the specific usage patterns of that fleet.
3) Vehicles where the mass of fuel is significant.

It will be appreciated that a time-varying mass and/or a time-varying gradient may be represented in the statistical domain, and that such a representation can be considered as a non-time-varying representation of a time-varying mass and/or time-varying gradient.

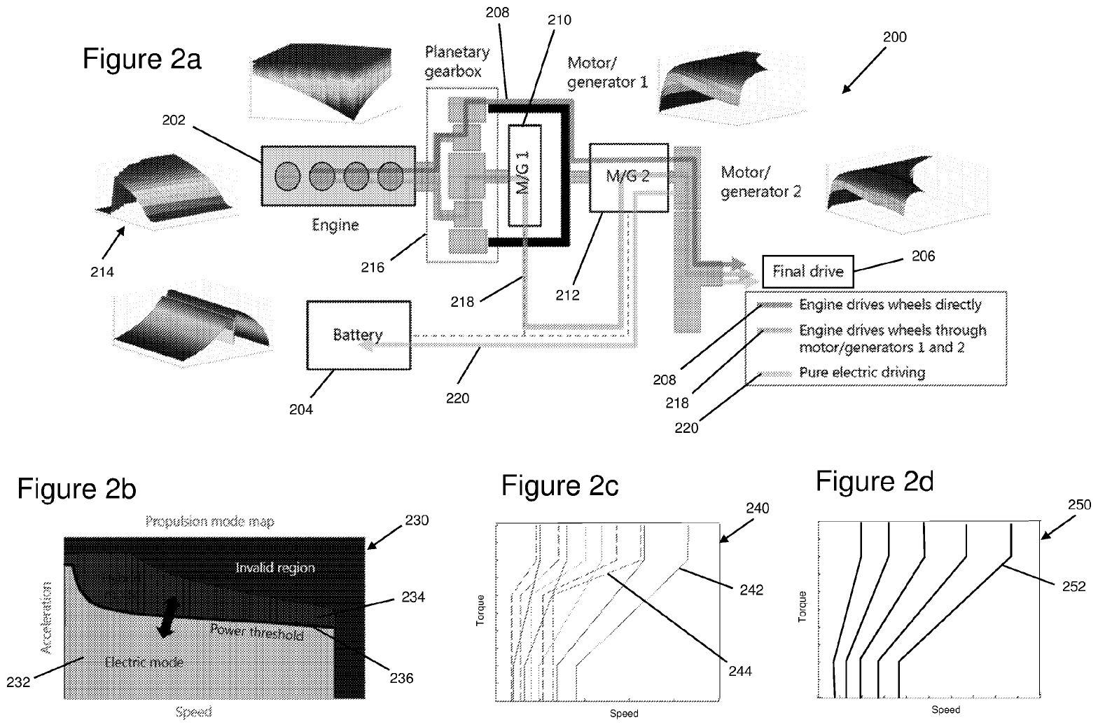

FIG. 2a shows an example of a driveline 200 of a hybrid vehicle, which includes a number of components. In this example, the driveline 200 includes two energy sources: an internal combustion engine 202 and a battery 204. The final drive of the car 206 is shown as an energy sink.

A component-efficiency-map is shown associated with some of the main components in the driveline. For example, an engine-efficiency-map 214 is shown associated with the engine 202. The component-efficiency-maps associate component efficiency values with a plurality of component-operating-conditions of the component. The specific component-operating-conditions can vary from component to component. For example, for the engine 202 the component-operating-conditions can be speed and torque, and for the battery the component-operating-conditions can be power and state of charge.

A control strategy must be defined in order to determine how the driveline operates for specific vehicle operational requirement (such as speed and acceleration). Control parameters are associated with the control strategy. The main aspects of the control strategy are listed in the table below, along with associated control parameters. The values of one or more control parameters can together be referred to as a control-state-map. These are discussed in more detail later in this document.

| Aspect of control strategy | Control parameters |
|---|---|
| Propulsion-mode-of-operation: the choice | power-threshold-lines |
| of which energy source(s) are used to drive | |
| the driveline, for example whether a vehicle | |
| is being driven purely with electrical power | |
| (with the engine switched off), purely with | |
| engine power, or with a combination of | |
| engine and electrical power | |
| Power-split-mode-of-operation: In | Discussed in more detail below |
| propulsion-modes-of-operation where the | |
| driveline is being driven by a combination of | |
| energy sources (e.g. engine and electrical | |
| power), the power-split-mode-of-operation | |
| defines how much of the power demand | |
| comes from each energy source. | |
| Gear-mode-of-operation: the choice of | gear-threshold-lines, which may include |
| which of a finite number of gear ratios is | up-gear-threshold-lines and |
| engaged | down-gear-threshold-lines |

Power-threshold-lines and gear-threshold-lines are examples of switchover-thresholds.

In the example in FIG. 2a, the driveline-efficiency-processor can determine how much of the power demand should be obtained from the engine 202 and how much from the battery 204. The control-state-map can also define which of a plurality of gear ratios (corresponding to a plurality of powerflows in the gearbox) should be used for specific output requirements of the vehicle.

When the vehicle is in the hybrid-mode-of-operation 234, the power demand at the wheels is provided by more than one power source. In a hybrid electric vehicle, the power sources can be an engine and one or more electric motors. Different methods may be used to determine the power-split-mode-of-operation, i.e. how the power demand is divided between the different power sources.

For example, consider a driveline with two power sources, an engine and an electric motor. The table below enumerates some different control strategies that may be used to determine the engine output power, along with the associated control parameters. The required power output of the electric motor can then be calculated by subtracting the engine power from the total power demand. Note that the power output of the electric machine can be negative (therefore generating electricity) if the power output of the engine exceeds the power demand.

| Control strategy | Control parameters |
|---|---|
| The operation of the engine is based on the | Threshold engine power |
| engine power output. A threshold engine | |
| power defines the engine power output, such | |
| that i) when the power demand is less than the | |
| threshold engine power, the engine power | |
| output matches the threshold engine power, | |
| and ii) when the power demand is greater | |
| than the threshold engine power, the engine | |
| power matches the power demand, with an | |
| offset to generate the minimum power for the | |
| ancillary systems. | |
| The operation of the engine is based on the | Engine power levels |
| engine power output. A number of different | Number of engine power levels (which is an |
| engine power levels are processed, each of | example of driveline-efficiency-processor- |
| which is a different control-state-of- | detail-level 116) |
| operation. The engine power level | |
| control-state-of-operation that gives the | |
| best system efficiency is selected. | |
| The engine is always operated at the same | Engine operating point |
| operating point, which may be its most | |
| efficient operating point. The most efficient | |
| operating point is the engine speed and | |
| engine torque at which the engine has the | |
| highest efficiency. | |
| The engine is operated along a line that | Engine operating line |
| defines torque as a function of speed. This | Number of points along engine operating |
| may be the line that defines the most efficient | line (which is an example of driveline- |
| operating torque as a function of speed. A | efficiency-processor-detail-level 116) |
| number of different points along this line are | |
| processed, each of which is a different control- | |
| state-of-operation. The control-state-of- | |
| operation that gives the best system efficiency | |
| is selected. | |

FIG. 2b shows an example propulsion-mode-map 230, which is an example of a control-state-map, or part of a control-state-map, in that it illustrates values for a power-threshold-line 236 example of a control parameter. The propulsion-mode-map 230 of FIG. 2b is for a vehicle that can operate in an electric-mode-of-operation 232 or a hybrid-mode-of-operation 234. It will be appreciated that the propulsion-mode-map 230 could be expanded to also include an engine-only mode of operation (not shown) if required. The propulsion-mode-map 230 shows vehicle acceleration on the vertical axis and vehicle speed on the horizontal axis. A power-threshold-line 236 defines a boundary between the electric-mode-of-operation 232 and the hybrid-mode-of-operation 234. The power-threshold-line 236 defines a plurality of speed-acceleration values at which the vehicle will change propulsion mode between hybrid-mode-of-operation and electric-mode-of-operation. The electric-mode-of-operation 232 and the hybrid-mode-of-operation 234 are examples of control-states-of-operation, and the power-threshold-line 236 is an example of a switchover-threshold.

FIG. 2c shows an example gear-shift-map 240, which is another example of a control-state-map, or part of a control-state-map, in that it illustrates values for the gear-threshold-lines 242, 244 examples of control parameters. The gear-shift-map 240 is for a gearbox that has 6 gear ratios. The gear-shift-map 240 shows torque on the vertical axis and rotational speed on the horizontal axis. The gear-shift-map 240 includes 5 up-gear-threshold-lines 242 (shown as solid lines), which define transition points to the next (higher) gear. The gear-shift-map 240 also includes 5 down-gear-threshold-lines 244 (shown as dashed lines), which define transition points to the preceding (lower) gear. When the gearbox is operating in any specific (nth) gear, the vehicle can be said to operate in the nth gear-mode-of-operation. In examples where the simulation is in the statistical domain, the gear-shift-map 250 is simplified, as illustrated in FIG. 2d. There is no need for separate up-gear-threshold-lines and down-gear-threshold-lines; only one gear-threshold-line 252 is needed to define the transition between two consecutive gear-modes-of-operation. The gear-modes-of-operation are examples of control-states-of-operation, and the gear-threshold-lines are examples of switchover thresholds.

Returning to FIG. 2a, where a Prius®-type power-split drivetrain is pictured, the first motor/generator 210 mainly operates as a generator, and is also used for engine starting. The second motor/generator 212 enables electric-only driving, can provide an electrical boost when the engine 202 is running, and can also be used for regenerative braking.

The driveline 200 of FIG. 2a has three powerflow paths, mechanical 208, series 218, and electrical 220. Each of the powerflow paths corresponds to a control-state-of-operation. The mechanical 208 power path is a direct powerflow from the engine 202 to the wheels 206, in the same way as in a conventional vehicle. In the mechanical 208 mode of operation, a planetary gearbox 216 is used such that the powerflow path bypasses the first motor/generator 210. The series 218 power path effectively decouples the engine 202 speed from the wheel 206 speed. This can provide for high efficiency because the engine can operate at high speed, and therefore high efficiency, even when the wheel speed is low. In the series 218 mode of operation, the planetary gearbox 216 is used such that the powerflow path includes the first motor/generator 210. The electrical 220 power path is an electric-only driving mode where the vehicle is powered by the battery 204 through second motor/generator 212. In the reverse direction, kinetic energy from deceleration can be converted to electricity by the second motor/generator 212, and stored in the battery 204. Therefore, the battery 204 can also be considered as an energy sink.

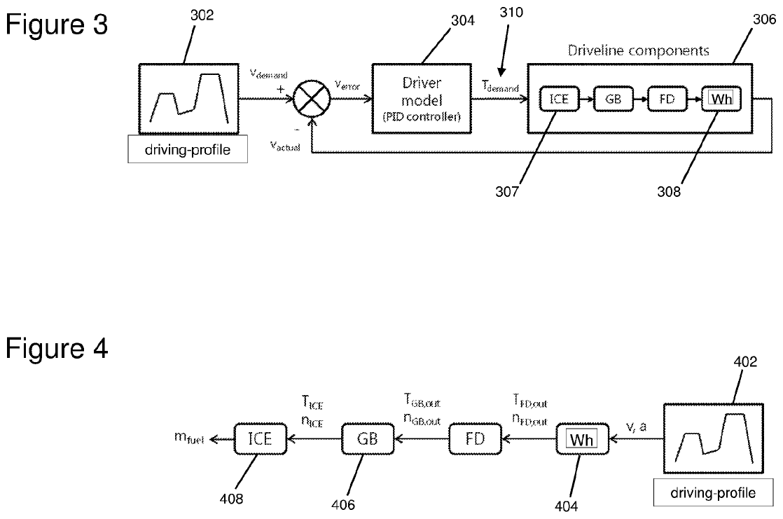

FIG. 3 illustrates a forward-facing simulation of a driveline for a specific driving-profile 302. The example illustrated here is automotive, but the method can also be applied to other drivelines. This model incorporates a driver model 304 that provides a torque demand for the driveline 306 in order to follow the speed profile defined by the driving-profile 302. The driver model can be a PID controller. The torque requirement is then passed along the chain of driveline components 306 from the engine 307 to the wheels 308, where the vehicle speed is updated and is used at the next simulation timestep to determine the torque demand 310 for the driveline 306.

FIG. 4 illustrates a backward-facing simulation of a driveline for a specific drive cycle 402. The simulation starts by calculating a required tractive force at the wheels 404 for the drive cycle 402, taking into account the drag forces caused by air resistance and friction of the wheels against the road. As discussed above, if the driving-profile includes road gradients or time-varying mass, these are accounted for in the tractive force equation. The simulation then “tracks back” through each component in turn, calculating speeds, torques and/or powers (as appropriate for the specific components) throughout the drivetrain.

In some examples, for each preceding component in the driveline, the simulation can determine one or more of the following for each component:
(a) a component-required-speed;
(b) a component-required-power; and
(c) a component-required-torque
based on one or more of:
(d) a component-efficiency-map for the component;
(e) a subsequent-component-required-speed;
(f) a subsequent-component-required-power; and
(g) a subsequent-component-required-torque;
or other parameters as appropriate.

In this example, the simulation tracks back from the wheels 404 to a gearbox 406 to an internal combustion engine 408 T (torque) and n (speed) values are identified in FIG. 4 at the input to each component. The volume of fuel consumed over the driving-profile can then be calculated from the engine output torque and speed values. This can use a fuel flow rate map for the engine 408.

The backwards simulation method can be simpler and faster than the forwards simulation of FIG. 3. Backwards simulation does have limitations, for example in modelling the driver behaviour: backward simulation assumes that the driver follows the drive cycle exactly, whereas in forwards simulation the driver model can “overshoot” and correct the error, like a human driver. Despite these limitations, the backwards-facing method can be sufficiently accurate for performing a concept design.

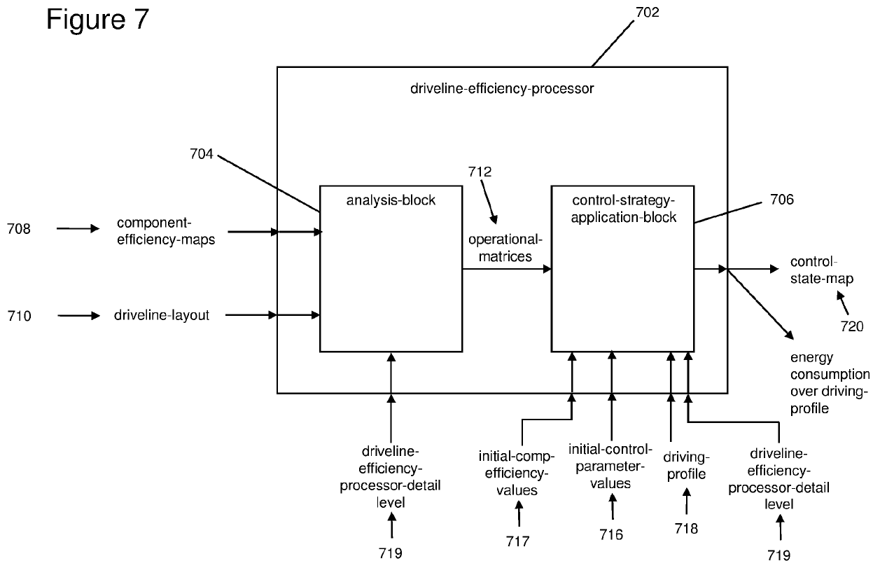

FIG. 7 shows an example of a driveline-efficiency-processor 702 (also 106 in FIG. 1), which can be used to calculate driveline-metrics. The driveline-efficiency-processor 702 includes an analysis-block 704 and a control-strategy-application-block 706.

The analysis-block 704 can implement the process described in FIG. 3. The inputs to the analysis-block 704 are: (i) component-efficiency-maps 708; (ii) the driveline-layout 710; and a driveline-efficiency-processor-detail-level 719, which corresponds to the driveline-efficiency-processor-detail-level 116 in FIG. 1. The component-efficiency-maps 708 can be generated by component-efficiency-processors, such as the ones illustrated in FIG. 1.

The analysis-block 704 generates a set of operational-matrices 712 as an output. The set of operational-matrices 712 provides information about the efficiency of the components in the driveline for each control-state-of-operation, for a plurality of vehicle operational requirements (such as speed and acceleration values).

The control-strategy-application-block 706 processes the operational-matrices 712, initial-control-parameter-values 716, a received driving-profile 718, and initial-component-efficiency-values 717 in order to generate a suitable control-state-map 720 for the driving-profile 718. This can involve iteratively calculating the efficiency of the driveline for a plurality of different control-state-maps.

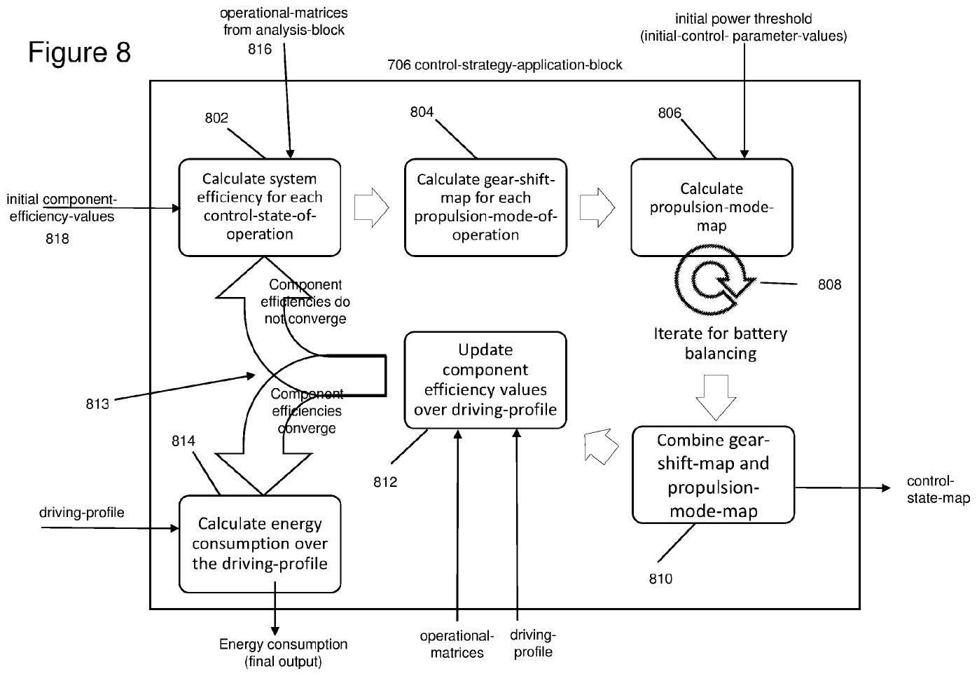

FIG. 8 illustrates schematically a method of operation of the control-strategy-application-block 706.

At step 802, the overall system efficiency is calculated for each control-state-of-operation (for example, this could be for each gear ratio and for each propulsion mode).

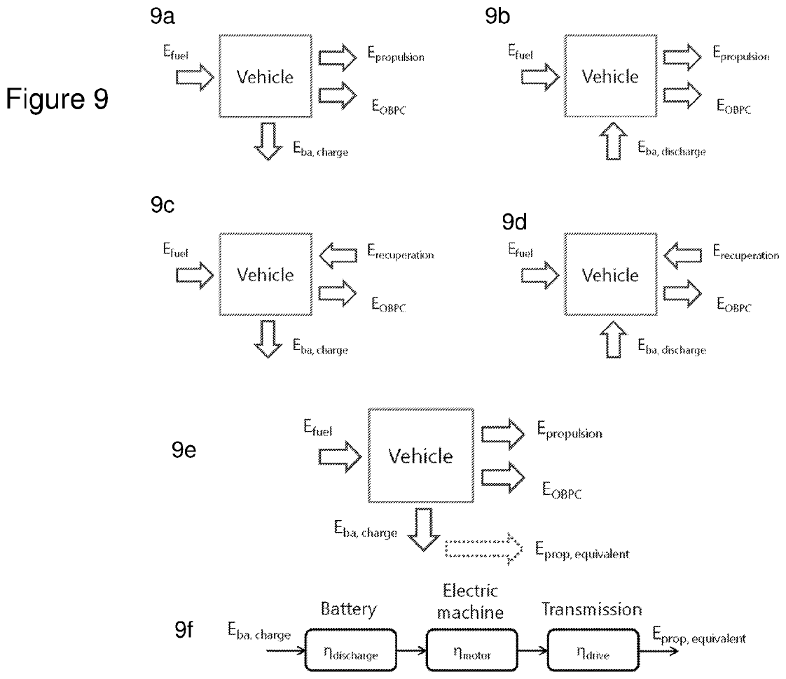

One method of calculating system efficiency is illustrated in FIG. 9. When the driveline contains more than one energy source and/or energy sink (for example, a hybrid electric vehicle that has an internal combustion engine and an electric motor), it is not appropriate to calculate efficiency as power out divided by power in because the power has traced different paths through the system and these paths have different efficiencies. Consider a system with two energy sinks, for example a hybrid vehicle in which power is used for propulsion and also stored in a battery. It is possible to calculate equivalent-propulsion-power—for example, if some power is used to charge the battery, it is possible to calculate what the equivalent propulsion power would have been if that power had been used for propulsion instead (see FIG. 9e). The two power outputs (power actually used for propulsion, and equivalent-propulsion-power from the battery) are at the same point in the system. It is therefore possible to add them together to determine the total power output. By dividing this power output by the power coming into the system from the engine, the overall-equivalent-system-efficiency can be obtained.

Some powers can be either inputs or outputs depending on the direction of the powerflow. FIG. 9 illustrates four powerflow conditions. The battery can be charging (FIGS. 9a and 9c) or discharging (FIGS. 9b and 9d), and the vehicle can be accelerating (FIGS. 9a and 9b) or decelerating (FIGS. 9c and 9d). The calculation of overall-equivalent-system-efficiency can be carried out separately for each of the four powerflow conditions.

Calculating equivalent-propulsion-power requires knowing the component efficiency values over the driving-profile, in order to “track” power from one place in the drivetrain to another (see FIG. 9f). Component efficiency values over the driving-profile will depend on the control-state-map. This is why the iteration loop in FIG. 8 can be beneficial.

Returning to FIG. 8, the overall system efficiency for each control-state-of-operation is calculated in step 802, as described above, using the operational-matrices 816 received from the analysis-block (not shown in FIG. 8) and initial-component-efficiency-values 818. The initial-component-efficiency-values 818 are used to provide a starting point for the loop, in order to provide initial values so that system efficiency can be calculated the first time, and in order to provide a baseline for the subsequent convergence check (as will be discussed below). At step 802, the overall system efficiency is calculated for all speed-acceleration values.

At step 804, the gear ratio for each speed-acceleration operating point is chosen. In some examples, this choice can be determined by which ratio gives the best overall system efficiency. For example, for each and every speed-acceleration operating point, the system efficiency for each gear-mode-of-operation is compared, and the gear-mode-of-operation with the best system efficiency is selected as a preferred gear-mode-of-operation for the speed-acceleration operating point. Once all of the preferred gear-modes-of-operation have been selected, the values for the values for the gear-threshold-lines between consecutive gear ratios can be determined. In this way, the control-strategy-application-block effectively determines a gear-shift-map similar to that illustrated in FIG. 2d. In this example, a gear shift map is calculated for each propulsion-mode-of-operation. Therefore if there are p propulsion-modes-of-operation and g gear ratios, there will be p gear shift maps and p*g control-states-of-operation.

At step 806, a propulsion-mode-map is set, similar to that illustrated in FIG. 2b. In this way, appropriate switchover thresholds (power-threshold-lines) between propulsion-modes-of-operation are defined. In this example, a sub-loop 808 is applied within step 806, in order to achieve a target net-battery-charge-increase over the driving-profile. The net-battery-charge-increase value represents a degree to which the charge level of the battery has increased (or decreased) over the driving-profile. The sub-loop 808 begins with an initial value of the power-threshold-line 236, which is received by the control-strategy-application-block 706 as an initial-control-parameter-value. The power-threshold-line 236 defines the threshold at which the vehicle will change propulsion mode between hybrid-mode-of-operation and electric-mode-of-operation. The net-battery-charge-increase value over the driving-profile is determined for this power-threshold-line.

The value of the power-threshold-line is then changed in order to bring the net-battery-charge-increase of the next iteration of sub-loop 808 closer to the target value. After several iterations, the net-battery-charge-increase value will converge. In this way, the sub-loop 808 determines a net-battery-charge-increase value over the driving-profile for a plurality of control-state-maps; compares the net-battery-charge-increase values with each other or a predetermined threshold; and based on the comparison, selects one of the plurality of control-state-maps as for further processing.

In some examples, it can be advantageous for the battery charge level to be balanced over a driving-profile. In such an example, the processing at step 808 can result in a propulsion-mode-map for which the net-battery-charge-increase value is close to zero.

At step 810, the gear-shift-map identified at step 804 and the propulsion-mode-map selected at step 806 are combined to provide a single control-state-map

At step 812, the component efficiency values are updated. The new component efficiencies are calculated based on the driving-profile, the control-state-map determined at step 810, and on the operational-matrices calculated by the analysis-block 704 in FIG. 7.

After step 812, for each iteration of the loop after the first, the method determines whether or not each of the latest component efficiency values are acceptable and satisfy a predetermined criterion, for example whether or not they have converged to an acceptable extent. An acceptable-tolerance-value can be used to define whether or not the component efficiency values have converged to an acceptable extent. Such an acceptable-tolerance-value is also an example of a driveline-efficiency-processor-detail-level 116. That is, a high acceptable-tolerance-value gives fewer iterations of the loop and therefore finds the answer faster, a smaller acceptable-tolerance-value will result in more iterations but a more accurate result over all.

The result of the determination at step 812 is shown schematically by the split in the arrows 813 in FIG. 8. For example, the component efficiency values could be considered to have converged if the values match to within a defined percentage. If the efficiency values for each component have converged, then the output is the final driveline-efficiency-metric. In this example the driveline-efficiency-metric is representative of energy consumption over the driving profile. The total fuel consumption over the driving-profile can then be calculated.

If the efficiency values for each component have not converged following the processing at step 812, then the method returns to step 802 where the overall system efficiency is calculated for each control-state-of-operation, but this time using the component-efficiency-values calculated at step 812 instead of the initial-component-efficiency-values 818.

The method of FIG. 8 can be generalised as providing the following functionality:
a) determining a latest-control-state-map (method steps 802, 804, 806, 808, 810);
b) determining latest-component-efficiency-values for the driveline over the driving profile based on the set of operational-matrices and the latest-control-state-map (step 812); and
c) determining whether or not the latest-component-efficiency-values satisfy a predetermined criterion (the split in arrows 813); and
   if the latest-component-efficiency-values satisfy the predetermined criterion, then: determine the driveline-efficiency-metric based on the latest-component-efficiency-values and the latest-control-state-map; and
   provide data representative of (i) the latest-control-state-map; and/or (ii) the driveline-efficiency-metric as an output (step 814);
   if the component efficiency values do not satisfy the predetermined criterion, then: determine a revised latest-control-state-map based on the latest-component-efficiency-values (method steps 802, 804, 806, 808, 810) and return to step b).

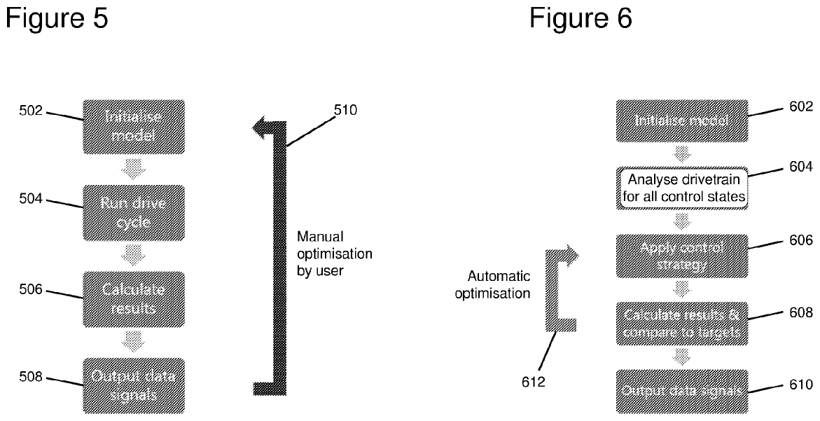

FIG. 5 illustrates an example process flow for simulation of a driveline over a driving-profile. As discussed above with reference to FIGS. 2b, 2c, and 2d, a control-state-map defines how the driveline will be controlled when it is in use. For example, the control-state-map may define which of a plurality of gear ratios in a gearbox is used. In hybrid applications, the control-state-map may also define a propulsion-mode-of-operation, such as electric only, hybrid mode or engine only.

At step 502, a model is initialised. Such initialisation can include defining the components to be used in the drivetrain, how they are connected, the appropriate values of component parameters and component efficiency maps, and appropriate values of control parameters. At step 504, a simulation of a driving-profile is run for the model that was initialised at step 502. In a first iteration, the simulation can be run for an initial control-state-map, which defines how the driveline is controlled for specific vehicle-operational-requirements (such as speed and acceleration values as defined by the driving-profile).

At step 506, the results of the simulation are calculated in order to generate data signals, which are output at step 508. The data signals are indicative of the efficiency of the driveline, when controlled in accordance with the control-state-map that was used at step 504. The data signals can also be indicative of the control-state-map that was used in the previous iteration of the simulation.

At step, 510, a user manually adjusts the control-state-map with a view to improving/optimising performance. This can be with the intention of improving efficiency. Then, with the adjusted control-state-map, the method returns to step 502 to initialise the new model, before a new simulation is run at step 504.

The method of FIG. 5 can be inefficient (in terms of processing resource and time) because each iteration around the loop with a different control-state-map requires intensive processing. The process illustrated in FIG. 5 calculates the component speeds and torques (step 504) only for the specified control state at each timestep. If the control-state-map is changed in step 510, it is necessary to run a new driving-profile simulation so that the correct control state can be applied at each timestep.

FIG. 6 illustrates an example process flow of the improved method of generating a control-state-map based on a simulation of a driving-profile. This method calculates the operational-matrices for all components for all control-states-of-operation, so if the control-state-map is changed, a different pre-calculated state can be selected, eliminating the need to re-run the simulation.

At step 602, a model is initialised, which can be similar to step 502.

At step 604, the method analyses the drivetrain for all control states. This step is carried out by the analysis-block 704, following the process defined in FIG. 4. In this example, step 604 involves, for a plurality of vehicle output speed-acceleration values, calculating the operational-matrices of each component in the driveline, for each control-state-of-operation. This can involve applying required speed and acceleration values to the wheels of the vehicle, calculating the tractive force, and working a simulation back through the driveline to the energy sources. The control-states-of-operation in this example can include a combination of (i) one of a plurality of modes of propulsion; and (ii) one of a plurality of gear ratios.

The output of step 604 can be a set of operational-matrices for each component for each control state of the driveline. The operational-matrices contain component values (for example, speeds, torques, and/or power values) as a function of vehicle speed and acceleration. Because step 604 involves the calculation of matrices for every drivetrain control state, the optimisation loop (606, 608, 612) simply selects the optimum combination of the operational-matrices which have already been calculated, in order to attain the best overall system efficiency (as described in FIG. 9). As step 604 (the most computationally intense part of the process) is carried out by the analysis-block 704 and therefore outside the optimisation loop 612, the process in FIG. 6 is significantly faster than the simulation process illustrated in FIG. 5.

At step 606, the method applies an initial control-state-map. The initial propulsion-mode-map is determined by choosing an initial threshold power value. This defines which of a plurality of propulsion modes to use as a function of the vehicle speed and acceleration. In some examples, the selection of which gear ratio (corresponding to one of a plurality of available gear ratios) should be used, is determined based on which ratio gives the best overall system efficiency. At step 608, the method involves calculating the overall-equivalent-system-efficiency for the control-state-map that was applied at step 606. For the first iteration of the loop this generates an initial driveline efficiency value. For subsequent iterations that apply additional control-state-maps, this generates additional driveline efficiency values. Step 608 also includes comparing the results to one or more targets. As discussed above, such targets can include convergent component efficiency values, and optionally a target net-battery-charge-increase over the driving-profile.

At step 612, the method then includes applying an automatic optimisation loop for retuning to step 606 to recalculate and apply a different control-state-map. The 606-608-612 loop in FIG. 6 is an implementation of the control-strategy-application-block of FIG. 7, and also corresponds to the loop in FIG. 8.

This automatic optimisation loop then continues until the targets at step 608 are satisfied, at which time output data signals are provided at step 610. The output data signals can be representative of a control-state-map that defines which of the control-states-of-operation should be applied for a range of vehicle speed-acceleration values, and a system-efficiency value associated with vehicle operation using the control-state-map for the drive cycle.

Notably, step 604 of calculating operational-matrices for all components and all control-states-of-operation, which can be relatively processing-intensive, is outside of the optimisation loop 612. This enables the method of generating a control-state-map to be very efficient in terms of the amount of processing that is required, and also the time taken to optimise the control-state-map.

1. A system for modelling a driveline, wherein the driveline comprises a plurality of components, the system comprising:
a component-efficiency-processor (104a, 104b) configured to:
receive a component model (102a, 102b) for one or more of the plurality of components; and
generate a component-efficiency-map for the one or more components based on the received corresponding component model (102a, 102b); and
a driveline-efficiency-processor (106) configured to generate a driveline-efficiency-metric (108) for the driveline based on (i) the component-efficiency-maps for the one or more of the plurality of components, (ii) a driveline-layout (110) representative of a layout/inter-engagement of the plurality of components, and (iii) one or more driving-profiles.

2. The system of claim 1, wherein the driveline-efficiency-processor is configured to generate one or more additional driveline-metrics based on the received corresponding component model (102a, 102b), wherein the one or more additional driveline-metrics are representative of one or more of the following characteristics: packaging size, power rating, durability, driveability, noise and vibration characteristics.

3. The system of claim 1, wherein the component-efficiency-processor (104a, 104b) is configured to generate the component-efficiency-map based on a component-detail-level (114).

4. The system of claim 3, wherein the component-efficiency-processor (104a, 104b) is configured to:
make different physical or mathematical assumptions when generating the component-efficiency-map based on the component-detail-level; and/or
change the number of points used for generating the component-efficiency-map based on the component-detail-level.

5. The system of claim 1, wherein the component models comprise component-form-information representative of physical dimensions of the associated component, and the driveline-efficiency-processor (106) is further configured to:
generate a driveline-packaging-metric based on (i) the component-form-information for the one or more of the plurality of components, and (ii) the driveline-layout.

6. The system of claim 1, wherein the driveline-efficiency-processor (106) is further configured to:
convert one or more driving-profiles from the time-domain into a non-time-varying form; and
generate the driveline-efficiency-metric (108) based on the non-time-varying form of the one or more driving-profiles.

7. The system of claim 1, wherein the driveline-efficiency-processor (106) is further configured to generate the driveline-efficiency-metric for the driveline based on a time-varying mass of a vehicle associated with the driveline over the one or more driving-profiles.

8. The system of claim 7, wherein the driving-profile comprises information about the time-varying mass of the vehicle.

9. The system of claim 1, wherein the driveline-efficiency-processor (106) is further configured to generate the driveline-efficiency-metric for the driveline based on a variable gradient associated with the one or more driving-profiles.

10. The system of claim 9, wherein the driving-profile comprises information about the variable gradient.

11. The system of claim 1, wherein the driveline-efficiency-processor (106) is configured to apply a tractive force equation when generating the driveline-efficiency-metric (108), wherein the tractive force equation is configured to determine tractive force required for a time-varying mass and/or a variable gradient associated with the one or more driving-profiles.

12. The system of claim 1, wherein the driveline-efficiency-processor (106) is further configured to:
process a plurality of different drivelines and generate one or more driveline-metrics for each of the plurality of drivelines;
use the driveline-metrics to select a driveline, considering one or more of a range of performance targets.

13. The system of claim 12, in which the plurality of drivelines have variations in one or more or the following inputs:
driveline-layouts;
component models;
component-efficiency-maps;
component parameters;
wherein each combination of inputs represents a different driveline.

14. The system of claim 1, wherein the driveline-efficiency-processor (106) is further configured to:
process a driveline with a plurality of different control parameters and generate one or more driveline-metrics for each of the plurality of control parameters;
use the driveline-metrics to select a set of control parameters, considering one or more of a range of performance targets.

15. A driveline-efficiency-processor for a driveline comprising a plurality of components, wherein the driveline can be operated according to a plurality of control-states-of-operation, wherein the driveline-efficiency-processor comprises:
an analysis-block configured to:
receive a plurality of component-efficiency-maps that are associated with respective ones of the plurality of components in the driveline;
receive a driveline-layout representative of a layout/inter-engagement of the plurality of components;
provide as an output, a set of operational-matrices for each component, wherein the set includes a matrix for each control-state-of-operation; and
a control-strategy-application-block configured to:
receive the set of operational-matrices;
receive a driving-profile that represents a plurality of vehicle-operational-requirements;
process the driving-profile and the set of operational-matrices for each component to determine one or more control-state-maps;
for the one or more control-state-maps, process the driving-profile and the set of operational-matrices for each component to determine a driveline-efficiency-metric; and provide as an output, data representative of (i) a control-state-map associated with the driveline-efficiency-metric; and/or (ii) the driveline-efficiency-metric.

16. The driveline-efficiency-processor of claim 15, wherein the matrix for each control-state-of-operation in the set of operational-matrices comprises information about the efficiency of an associated component for a plurality of vehicle operational requirements.

17. The driveline-efficiency-processor of claim 15, wherein the control-strategy-application-block is configured to:
a) determine a latest-control-state-map;
b) determine latest-component-efficiency-values for the driveline over the driving profile based on the set of operational-matrices and the latest-control-state-map; and
c) determine whether or not the latest-component-efficiency-values satisfy a predetermined criteria; and
if the latest-component-efficiency-values satisfy the predetermined criteria, then:
determine the driveline-efficiency-metric based on the latest-component-efficiency-values and the latest-control-state-map; and
provide as an output, data representative of (i) the latest-control-state-map; and/or (ii) the driveline-efficiency-metric;
if the latest-component-efficiency-values do not satisfy the predetermined criteria, then:
determine a revised latest-control-state-map based on the latest-component-efficiency-values and return to step b).

18. The driveline-efficiency-processor of claim 17, wherein each control-state-map defines one or more switchover-thresholds between different control-states-of-operation, and wherein the control-strategy-application-block is configured to determine a revised latest-control-state-map by modifying the switchover-threshold(s).

19. The driveline-efficiency-processor of claim 17, wherein the control-strategy-application-block is configured to determine the latest control-state-map by:
determining a net-battery-charge-increase value over the driving-profile for a plurality of control-state-maps;
comparing the net-battery-charge-increase values with each other or a predetermined threshold; and
based on the comparison, selecting one of the plurality of control-state-maps as the latest control-state-map.

20. The driveline-efficiency-processor of claim 17, wherein the control-strategy-application-block is configured to determine the latest-control-state-map at step a) using initial-component-efficiency-values.

21. The driveline-efficiency-processor of claim 15, in which the control-strategy-application-block is configured to calculate the driveline-efficiency-metric and control-state-map using an iterative process:
process the set of operational-matrices for each component and initial component-efficiency-values to determine an initial driveline-efficiency-metric for each control-state-of-operation;
process the initial driveline-efficiency-metric for each control-state-of-operation in order to determine an initial control-state-map;
optionally, alter a power-threshold-line between different control-states-of-operation to achieve a specified target value of net-battery-charge-increase over the driving profile;
calculate updated component efficiency values over the driving-profile using the control-state-map;
compare the component efficiency values over the driving-profile with those calculated in a previous iteration (or, in the first iteration, with the initial component-efficiency-values);
if the component efficiency values over the driving-profile have not converged to within a defined limit, repeat the process from the beginning using the updated component efficiency values;
if the component efficiency values over the driving-profile have converged to within a defined limit, provide as an output data representative of (i) a final control-state-map and/or (ii) the final driveline-efficiency-metric.

22. The driveline-efficiency-processor of claim 15, wherein the control-states-of-operation comprise one or more of:
(i) one of a plurality of modes of propulsion;
(ii) one of a plurality of gear ratios; and
(iii) one of a plurality of power-split-modes-of-operation.

23. A method of modelling a driveline, wherein the driveline comprises a plurality of components, the method comprising:
receiving a component model (102a, 102b) for one or more of the plurality of components; and
generating a component-efficiency-map for the one or more components based on the received corresponding component model; and
generating a driveline-efficiency-metric (108) for the driveline based on (i) the component-efficiency-maps for the one or more of the plurality of components, (ii) a driveline-layout (110) representative of a layout/inter-engagement of the plurality of components, and (iii) one or more driving-profiles.

24. A method of processing for a driveline, wherein the driveline comprises a plurality of components, and wherein the driveline can be operated according to a plurality of control-states-of-operation, wherein the method comprises:
receiving a plurality of component-efficiency-maps that are associated with respective ones of the plurality of components in the driveline;
receiving a driveline-layout representative of a layout/inter-engagement of the plurality of components;
determining a set of operational-matrices for each component, wherein the set includes a matrix for each control-state-of-operation; and
receiving a driving-profile that represents a plurality of vehicle-operational-requirements;
processing the driving-profile and the set of operational-matrices for each component to determine one or more control-state-maps;
for the one or more control-state-maps, processing the driving-profile and the set of operational-matrices for each component to determine a driveline-efficiency-metric; and
providing as an output, data representative of (i) a control-state-map associated with the driveline-efficiency-metric; and/or (ii) the driveline-efficiency-metric.

25. A computer program configured to perform the method of claim 23.

26. A computer program configured to configure the system of claim 1.

27. A computer program configured to configure the system of claim 15.
